(19) United States
(12) Patent Application Publication
(10) Pub. No.: US 2026/0344301 A1
(43) Pub. Date: Oct. 29, 2026

(54) SUPERCONDUCTING QUANTUM CIRCUIT AND CHIP

(71) Applicant: YANGTZE DELTA INDUSTRIAL INNOVATION CENTER OF QUANTUM SCIENCE AND TECHNOLOGY, Suzhou (CN)

(72) Inventors: Baojun LU, Suzhou (CN); Runxiao ZHANG, Suzhou (CN); Zeyang ZHENG, Suzhou (CN); Hui YANG, Suzhou (CN); Zedong LI, Suzhou (CN); Huide ZHOU, Suzhou (CN); Tian LUAN, Suzhou (CN)

(21) Appl. No.: 19/062,083

(22) Filed: Feb. 25, 2025

Related U.S. Application Data
(63) Continuation of application No. PCT/CN2024/105303, filed on Jul. 12, 2024.

(30) Foreign Application Priority Data
Sep. 25, 2023 (CN) 202311239727.0

(51) Int. Cl. H10N 69/00; G06N 10/40; H10N 60/12; H10N 60/82

(52) U.S. Cl. CPC H10N 69/00; G06N 10/40; H10N 60/12; H10N 60/82

(57) ABSTRACT

The invention discloses a novel superconducting quantum circuit and chip, which relates to the technical field of superconducting quantum. The superconducting quantum circuit includes a quantum bit including a bit capacitor and a Josephson junction, the bit capacitor including two independent metal sheets, the Josephson junction being connected between either of the metal sheets and a ground plane in a spanned mode, a first coupling capacitor being formed between the two metal sheets, and a self-capacitor being formed between each of the metal sheets and the ground plane; and a signal transmission line, the signal transmission line being coupled with the quantum bit.

### CROSS-REFERENCE TO RELATED APPLICATIONS

The present application is a continuation of International Application No. PCT/CN2024/105303, with an international filing date of Jul. 12, 2024, which is based upon and claims priority to Chinese Patent Application No. 202311239727.0, filed on Sep. 25, 2023, the entire contents of all of which are incorporated herein by reference.

### TECHNICAL FIELD

The present disclosure relates to a technical field of superconducting quantum, and particularly to a novel superconducting quantum circuit and a chip.

### BACKGROUND

In conventional superconducting quantum chips, a bit capacitor is generally formed by a single, independent metal sheet and a chip, and the size of the bit capacitor in this form is comparable to that of a quarter-wavelength resonator in a meandering layout. With the increase of the number of the quantum bits, the quantum bits expand along two dimensional directions, at this time, the layout space reserved for XY control lines, Z control lines and read lines is smaller, which usually needs to sacrifice the isolation index between the signal lines to meet the wiring requirements. Compared with a cross-shaped bit capacitor, the bit capacitor based on a double-island structure is larger in size, leaving more layout space for the XY control line, the Z control line and the read line, which meets the wiring requirements without sacrificing the isolation index between the signal lines. However, the double-island structure has the following problems: first, the Josephson junction is connected between two metal sheets in a spanned mode (located in the center area of the bit capacitor). In other words, the Z control line must extend to the central area of the bit capacitor to apply the magnetic flux to the Josephson junction, which not only limits the layout of the resonator and the signal line, but also increases the coupling between the Z control line and the resonator. The bit capacitor based on a double-island structure is not flexible enough in design, which increases the complexity of the design and reduces the speed of the version iteration.

In summary, how to provide a solution for solving the above technical problem is an urgent problem for those skilled in the art.

### SUMMARY

The present disclosure aims at providing a superconducting quantum circuit and a chip, which can prevent the Z control line from extending to the central area of the bit capacitor, and provide a smaller size of a bit capacitor, and thus is conducive to improving the integration level of the chip, being flexible in design and reducing the design complexity.

In order to solve the above technical problem, the present disclosure provides a superconducting quantum circuit, comprising:
a quantum bit including a bit capacitor and a Josephson junction, the bit capacitor including two independent metal sheets, the Josephson junction being connected between either of the metal sheets and a ground plane in a spanned mode, a first coupling capacitor being formed between the two metal sheets, and a self-capacitor being formed between each of the metal sheets and the ground plane; and
a signal transmission line, the signal transmission line being coupled with the quantum bit.

Alternatively, the bit capacitor includes a first metal sheet and a second metal sheet, a size of the first metal sheet being smaller than a size of the second metal sheet, and the Josephson junction is connected between the first metal sheet and the ground plane in a spanned mode.

Alternatively, the superconducting quantum circuit further comprises:
a first substrate having the quantum bits formed on an upper surface of the first substrate; and
a second substrate having the signal transmission line formed on a lower surface of the second substrate.

Alternatively, the upper surface of the first substrate and the lower surface of the second substrate are both made of superconducting materials.

Alternatively, the superconducting quantum circuit further comprises:
a resonator coupled to the quantum bit and forming a second coupling capacitor between the resonator and each of the metal sheets.

Alternatively, the signal transmission line is in non-coplanar coupling with the quantum bit.

Alternatively, the signal transmission line comprises a Z control line which is coupled with the Josephson junction through mutual inductance;
the signal transmission line comprises an XY control line which is coupled with the bit capacitor through mutual capacitance.

Alternatively, the number of the quantum bit is multiple; and
the two adjacent quantum bits are fixedly coupled.

Alternatively, the number of the quantum bit is multiple; and
the two adjacent quantum bits are adjustably coupled.

In order to solve the above technical problem, the present disclosure further provides a superconducting quantum chip comprising the superconducting quantum circuit according to any one of the above steps.

The present disclosure provides a superconducting quantum circuit, the bit capacitor including two independent metal sheets, the Josephson junction being connected between either of the metal sheets and a ground plane in a spanned mode, which prevents the Z control line from extending to the central area of the bit capacitor. By adopting the quantum bit structure of the present disclosure, the size of the metal sheet which is not connected with the Josephson junction can be adjusted according to requirements. Therefore, the bit capacitor has smaller size, which is conducive to improving the integration level of the chip, being flexible in design and reducing the design complexity. The present disclosure further provides a superconducting quantum chip, which can achieve the above advantageous effects, and thus will not be described in detail herein.

### BRIEF DESCRIPTION OF THE DRAWINGS

In order to more clearly explain the embodiments of the present disclosure, drawings required in the embodiments will be briefly described below. Obviously, the drawings in the following description are some embodiments of the present disclosure. For those skilled in the art, other drawings may be obtained from these drawings without any creative effort.

FIG. 1 is a structural schematic diagram of a superconducting quantum circuit provided by the present disclosure;

FIG. 2 is a structural schematic diagram of another superconducting quantum circuit provided by the present disclosure;

FIG. 3 is a structural schematic diagram of another superconducting quantum circuit provided by the present disclosure;

FIG. 4 is an equivalent circuit model of a superconducting quantum circuit provided by the present disclosure;

FIG. 5 is a structural schematic diagram of a fixed substrate provided by the present disclosure;

FIG. 6 is a structural schematic diagram of another superconducting quantum circuit provided by the present disclosure;

FIG. 7 is a schematic diagram of an adjustable coupling provided by the present disclosure;

FIG. 8 is a schematic diagram of another adjustable coupling provided by the present disclosure;

FIG. 9 is a schematic diagram of a quantum bit circuit based on a double-island structure.

### DETAILED DESCRIPTION OF THE EMBODIMENTS

The core of the present disclosure is to provide a superconducting quantum circuit and a chip, which can prevent the Z control line from extending to the central area of the bit capacitor, and provide a smaller size of a bit capacitor, and thus is conducive to improving the integration level of the chip, being flexible in design and reducing the design complexity.

To make the purpose, technical solution, and advantages of the embodiments of the present disclosure clearer, the technical solutions of the embodiments of the present disclosure will be described clearly and completely as follows with reference to the drawings in the embodiments of the present disclosure. Obviously, the described embodiments are part of, but not all of, the embodiments of the present disclosure. Based on the embodiments of the present disclosure, all the other embodiments obtained by those skilled in the art without paying any creative work fall within the protection scope of the present disclosure.

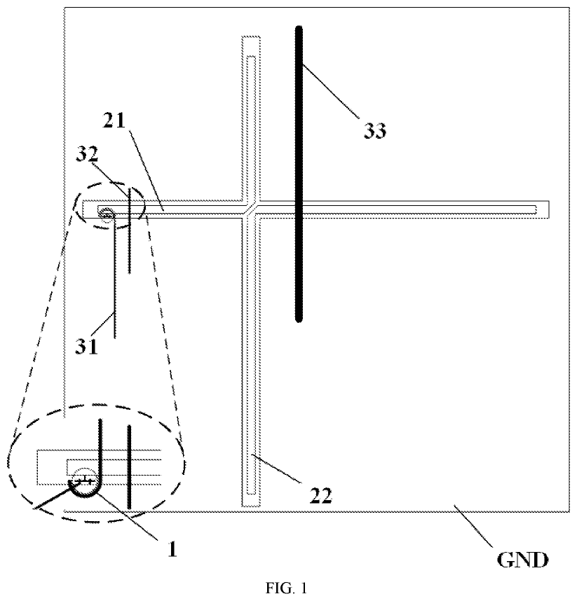

In a first aspect, with reference to FIG. 1, FIG. 1 is a structural schematic diagram of a superconducting quantum circuit provided by the present disclosure, the superconducting quantum circuit comprising:
a quantum bit including a bit capacitor and a Josephson junction 1, the bit capacitor including two independent metal sheets, the Josephson junction 1 being connected between either of the metal sheets and a ground plane Gnd in a spanned mode, a first coupling capacitor being formed between the two metal sheets, and a self-capacitor being formed between each of the metal sheets and the ground plane Gnd; and
a signal transmission line, the signal transmission line being coupled with the quantum bit.

The signal transmission line comprises a Z control line 31 which is coupled with the Josephson junction 1 through mutual inductance, the signal transmission line further comprises an XY control line 32 which is coupled with the bit capacitor through mutual capacitance, and the signal transmission line further comprises a read line 33. Obviously, the signal transmission line may also include other signal lines for controlling the quantum bits, which will not be described in detail herein. As a preferred embodiment, the signal transmission line and the quantum bit may adopt non-coplanar coupling, and the non-coplanar coupling facilitates the arrangement of more quantum bits as the number of quantum bits increases.

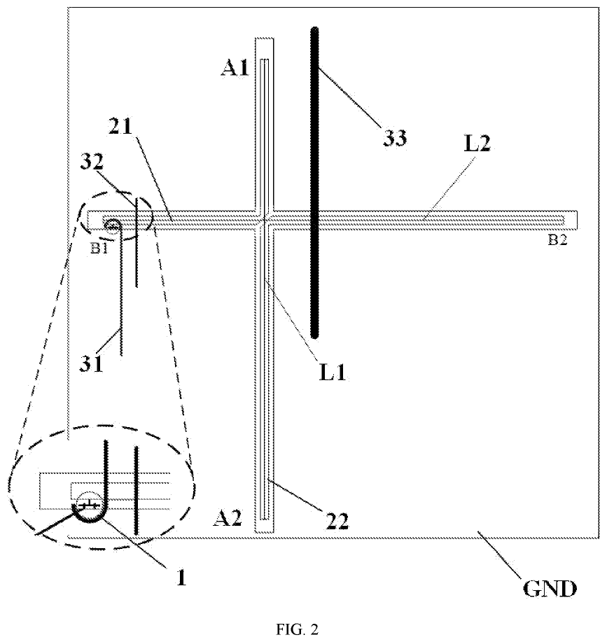

In this embodiment, the bit capacitor comprises two independent metal sheets, the two metal sheets including a first metal sheet 21 and a second metal sheet 22, each metal sheet has a first end and a second end, and the middle portion of the metal sheet is bent so that the metal sheet forms an L-shaped structure. In addition, the middle bending regions of the two metal sheets are close to each other but not in contact, and the ends of the two metal sheets are relatively distant. Referring to FIG. 2, the first end of the first metal sheet 21 and the first end of the second metal sheet 22 form a connection line L1, and the second end of the first metal sheet 21 and the second end of the second metal sheet 22 form a connection line L2, the connection line L1 and L2 intersect near the two bending regions.

The Josephson junction 1 may be connected between the first metal sheet 21 and a ground plane Gnd in a spanned mode, or it can be connected between the second metal sheet 22 and a ground plane Gnd in a spanned mode. It will be appreciated that the Josephson junction 1 is a superconductor-insulator-superconductor trilayer structure, and one side of the superconducting material on both sides of the Josephson junction 1 in this embodiment are connected to the first metal sheet 21 or the second metal sheet 22, and the other side is connected to the ground plane Gnd. The two metal sheets include a first end and a second end. The first end and the second end of the first metal sheet 21 are labeled A1 and B1, respectively, and the first end and the second end of the second metal sheet 22 are labeled A2 and B2, respectively. The Josephson junction 1 may be connected between A1 and the ground plane Gnd, or between B1 and the ground plane Gnd, or between A2 and the ground plane Gnd, or between B2 and the ground plane Gnd in a spanned mode, and may be designed according to actual engineering requirements, which is not specifically limited herein. With the structure of this embodiment, the Josephson junction 1 is connected between the end portion of the metal sheet and the ground plane Gnd in a spanned mode, i.e., the magnetic flux can act on the Josephson junction 1 directly at the end portion of the metal sheet, such that the Z control line 31 is prevented from extending to the central area of the bit capacitor.

The following is an example of the Josephson junction 1 being connected between the first metal sheet 21 and the ground plane Gnd in a spanned mode. The same applies when the Josephson junction 1 is connected between the second metal sheet 22 and the ground plane Gnd in a spanned mode. It will be appreciated that a small first coupling capacitor C₁₂ is formed between the two metal sheets, a self-capacitor C_{q1} is formed between the first metal sheet 21 and the ground plane Gnd, and a self-capacitance C_{q2} is formed between the second metal sheet 22 and the ground plane Gnd. The bit capacitor of the above structure may be equivalent to C_{q2} connected in series with C₁₂ and then connected in parallel with C_{q1}. Considering that the first coupling capacitor C₁₂ is much smaller than the self-capacitors C_{q1} and C_{q2}, the total bit capacitor formed by the structure provided in this embodiment may be equivalent to C_{q1}+C_{q2}≈C_{q1}. However, C_{q2} has little effect on the total bit capacitor value of the novel bit capacitor. In the design, the size of the self-capacitor corresponding to C_{q2} can be adjusted to any size according to the layout requirements of the signal transmission line. It will be appreciated that when the Josephson junction 1 is connected between the first metal sheet 21 and the ground plane Gnd in a spanned mode, the size of the second metal sheet 22 can be adjusted according to the actual layout requirements. Similarly, when the Josephson junction 1 is connected between the second metal sheet 22 and the ground plane Gnd in a spanned mode, the size of the first metal sheet 21 can be adjusted according to the actual layout requirements.

The bit capacitor provided by the embodiment has a smaller minimum size of the bit capacitor, which is conducive to improving the integration level of the chip, being flexible in design, thanks to the fact that C_{q2} can be adjusted to any value according to the layout requirements. When the number of control lines in the signal transmission line is changed (for example, the number of the resonator 4 mounted on a single read line 33 is changed or the coupling between the bit capacitors is modified from fixed coupling to adjustable coupling), there is no need to redesign the bit capacitor, and the adjustment of the size of the C_{q2} self-capacitor can meet the requirements of the signal line layout, which is conducive to improving the speed of the version iteration.

The present disclosure provides a superconducting quantum circuit, the bit capacitor including two independent metal sheets, and the Josephson junction 1 being connected between either of the metal sheets and a ground plane Gnd in a spanned mode, which prevents the Z control line 31 from extending to the central area of the bit capacitor. By adopting the quantum bit structure of the present disclosure, the size of the metal sheet which is not connected with the Josephson junction 1 can be adjusted according to the requirements. Therefore, the bit capacitor has smaller size, which is conducive to improving the integration level of the chip, being flexible in design and reducing the design complexity. On the basis of the above embodiment:
as an alternative embodiment, the bit capacitor comprises a first metal sheet 21 and a second metal sheet 22, the size of the first metal sheet 21 being smaller than that of the second metal sheet 22, and the Josephson junction 1 is connected between the first metal sheet 21 and the ground plane Gnd in a spanned mode.

In this embodiment, two independent metal sheets are selected to be of different sizes, the size of the first metal sheet 21 being smaller than that of the second metal sheet 22, and the Josephson junction 1 is connected between a smaller-sized independent metal sheet (i.e., the first metal sheet 21) and the ground plane Gnd in a spanned mode. The smaller-sized independent metal sheet and the ground plane Gnd form a small equivalent capacitor, the larger-sized independent metal sheet and the ground plane Gnd form a large equivalent capacitor, the smaller-sized independent metal sheet and the larger-sized independent metal sheet form a coupling capacitor, and the two large capacitors formed by the two independent metal sheets with different sizes and the ground plane Gnd are connected in series through the small coupling capacitor formed between the two independent metal sheets, wherein the equivalent capacitor formed between the smaller-sized independent metal sheet and the ground plane Gnd can be approximated as the total equivalent capacitor of the bit capacitor in the embodiment. The larger-sized independent metal sheet has less influence on the total equivalent capacitor value of the novel bit capacitor, which can be adjusted to any size as needed. In this embodiment, the size of the smaller-sized independent metal sheet is fixed, and the size of the larger-sized independent metal sheet can be adjusted according to the requirements, so that the size of the second metal sheet 22 can be adjusted in a wider range, and at the same time, a larger space is reserved for the layout of the signal transmission line.

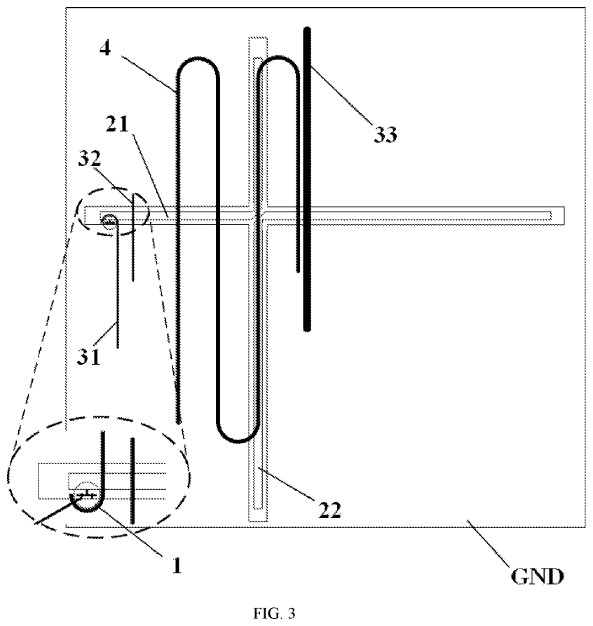

As an alternative embodiment, referring to FIG. 3, the superconducting quantum circuit further comprises:
a resonator 4 coupled to the quantum bit and forming a second coupling capacitor between the resonator 4 and each of the metal sheets.

In this embodiment, the superconducting quantum circuit further comprises the resonator 4, which can be in coplanar or non-coplanar coupling with the quantum bit, so as to exchange information with the quantum bit. Still, the following is an example of the Josephson junction 1 being connected between the first metal sheet 21 and the ground plane Gnd in a spanned mode, wherein the Josephson junction 1 is connected between the first metal sheet 21 and the ground plane Gnd in a spanned mode, and the equivalent series inductance is Lⱼ. A second coupling capacitor C_{g1} is formed between the resonator 4 and the first metal sheet 21, and a second coupling capacitor C_{g2} is formed between the resonator 4 and the second metal sheet 22. Considering that the Josephson junction 1 is connected between the ground plane Gnd and any one of the metal sheets in a spanned mode, it reduces the coupling strength between the Z control line 31 and the resonator 4 while facilitating the layout of the resonator 4 and the signal line to the greatest extent.

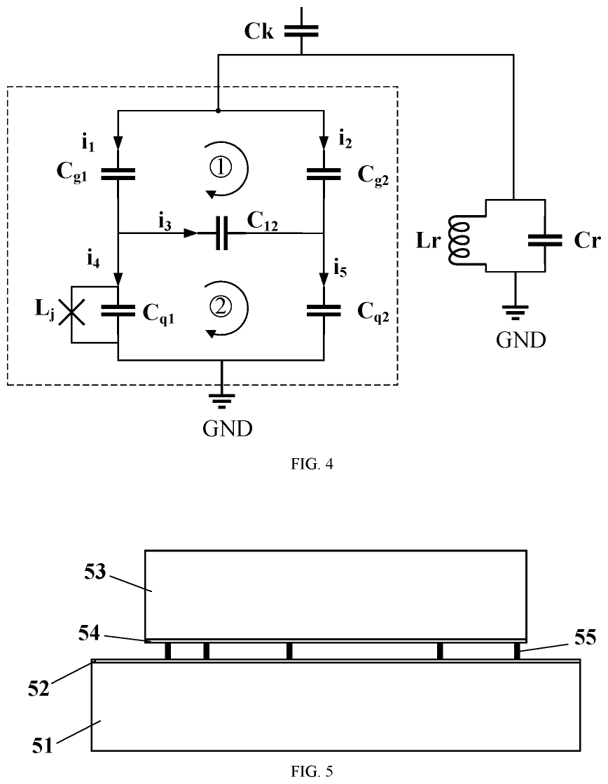

FIG. 4 is an equivalent circuit model of a superconducting quantum circuit provided by the present disclosure, wherein Cr is an equivalent capacitor formed between the quarter-wavelength resonator and the metal ground, Lr is an equivalent inductance formed by the quarter-wavelength resonator and the metal ground, i₁-i₅ are currents flowing through C_{g1}, C_{g2}, C₁₂, C_{q1} and Lⱼ, C_{q2}, respectively, and Ck is a coupling capacitor between the quarter-wavelength resonator and the read line 33.

According to Hoff's law, an equation set can be made as follows:

$$\{ \begin{matrix}\begin{matrix}I = {i}_{1} + {i}_{2} = {i}_{4} + {i}_{5} \\ {i}_{1} = {i}_{3} + {i}_{4}\end{matrix} \\ {i}_{5} = {i}_{2} + {i}_{3}\end{matrix} ;$$

[symbol]

$${i}_{2} \frac{1}{j ω {C}_{g 2}} - {i}_{3} \frac{1}{j ω {C}_{12}} - {i}_{1} \frac{1}{j ω {C}_{g 1}} = 0 ;$$

[symbol]

$${i}_{3} \frac{1}{j ω {C}_{12}} + {i}_{5} \frac{1}{j ω {C}_{q 2}} - {i}_{4} {Z}_{X} = 0 ;$$

wherein,

$${Z}_{X} = j ω {L}_{j} // \frac{1}{j ω {C}_{q 1}} = \frac{j ω {L}_{j} \frac{1}{j ω {C}_{q 1}}}{j ω {L}_{j} + \frac{1}{j ω {C}_{q 1}}} = \frac{j ω {L}_{j}}{1 - {ω}^{2} {L}_{j} {C}_{q 1}} ;$$

is the total equivalent impedance formed by the parallel connection of Lⱼ and C_{q1};

After expressing i₂, i₃, i₄, and is in terms of i₁, the impedance in the dashed box is obtained as:
Z=

$$\frac{\begin{matrix}\frac{{C}_{12} + {C}_{q 2} + {C}_{g 2}}{j ω {C}_{g 2} {C}_{q 2}} \{ - {ω}^{2} {C}_{q 2} {L}_{j} + \frac{1}{{C}_{g 1}} [ \begin{matrix}( {C}_{q 2} + {C}_{12} ) ( 1 - {ω}^{2} {L}_{j} {C}_{q 1} ) - \\ {ω}^{2} {C}_{12} {C}_{q 2} {L}_{j}\end{matrix} ] \} - \frac{1}{j ω {C}_{q 2}} \frac{{C}_{12}}{{C}_{g 1} {C}_{g 2}} \\ [ \begin{matrix}( {C}_{q 2} + {C}_{12} + {C}_{g 2} ) ( 1 - {ω}^{2} {L}_{j} {C}_{q 1} ) - \\ {ω}^{2} {C}_{12} {C}_{q 2} {L}_{j}\end{matrix} ]\end{matrix}}{\frac{{C}_{g 1} + {C}_{g 2}}{{C}_{g 2} {C}_{g 1}} [ ( {C}_{q 2} + {C}_{12} ) ( 1 - {ω}^{2} {L}_{j} {C}_{q 1} ) - {ω}^{2} {C}_{12} {C}_{q 2} {L}_{j} ] + 1 - {ω}^{2} {L}_{j} ( {C}_{q 1} + {C}_{q 2} )} ;$$

From numerator=0, considering that C_{g1}, C_{g2} and C₁₂ are much smaller than C_{q1} and C_{q2}, the series resonance frequency can be obtained as:

$$ω = \sqrt{\frac{{C}_{q 2} ( {C}_{q 2} + {C}_{12} + {C}_{g 2} )}{{L}_{j} [ ( {C}_{q 1} + {C}_{12} + {C}_{g 1} ) {C}_{q 2} ( {C}_{q 2} + {C}_{12} + {C}_{g 2} ) - {C}_{12}^{2} {C}_{q 2} ]}} \approx \sqrt{\frac{1}{{L}_{j} {C}_{q 1}}} ;$$

Similarly, from denominator=0, considering that C_{g1}, C_{g2} and C₁₂ are much smaller than C_{q1} and C_{q2}, the parallel resonance frequency can be obtained as:

$$ω = \sqrt{\frac{( {C}_{g 1} + {C}_{g 2} ) ( {C}_{q 2} + {C}_{12} ) + {C}_{g 1} {C}_{g 2}}{{L}_{j} [ ( {C}_{q 1} + {C}_{q 2} ) {C}_{g 2} {C}_{g 1} + {C}_{12} {C}_{q 2} ( {C}_{g 1} + {C}_{g 2} ) + {C}_{q 1} ( {C}_{g 1} + {C}_{g 2} ) ( {C}_{q 2} + {C}_{12} ) ]}} \approx \sqrt{\frac{1}{{L}_{j} {C}_{q 1}}} ;$$

As can be seen from the above equation, the total equivalent capacitor formed by the novel structure proposed in this embodiment is C_{q}≈C_{q1}, independent of C_{q2}. Therefore, the size of the second metal sheet 22 can be adjusted to any size according to the layout requirements of the signal transmission line. Further, when C_{q1}≈C_{q} and C_{q2}≈0, the bit capacitor of the novel structure has a minimum size.

As an alternative embodiment, with reference to FIG. 5, the superconducting quantum circuit further comprises:
a first substrate 51 having the quantum bits formed on its upper surface 52; and
a second substrate 53 having the signal transmission line and resonator 4 formed on its lower surface 54.

In this embodiment, the superconducting quantum circuit further comprises a fixed substrate including a first substrate 51 and a second substrate 53, wherein the Josephson junction 1, two metal sheets and the ground plane Gnd are formed on the upper surface 52 of the first substrate 51. The resonator 4, Z control line 31, XY control line 32, and read line 33 are formed on the lower surface 54 of the second substrate 53, and the ground planes of the first substrate 51 and the second substrate 53 are connected via indium column 55. As an alternative embodiment, the upper surface 52 of the first substrate 51 and the lower surface 54 of the second substrate 53 are both made of superconducting materials, such as tantalum, aluminum, etc., and the substrate material may be selected from, but not limited to, silicon or sapphire.

As an alternative embodiment, the number of the quantum bit is multiple; and two adjacent quantum bits are fixedly coupled.

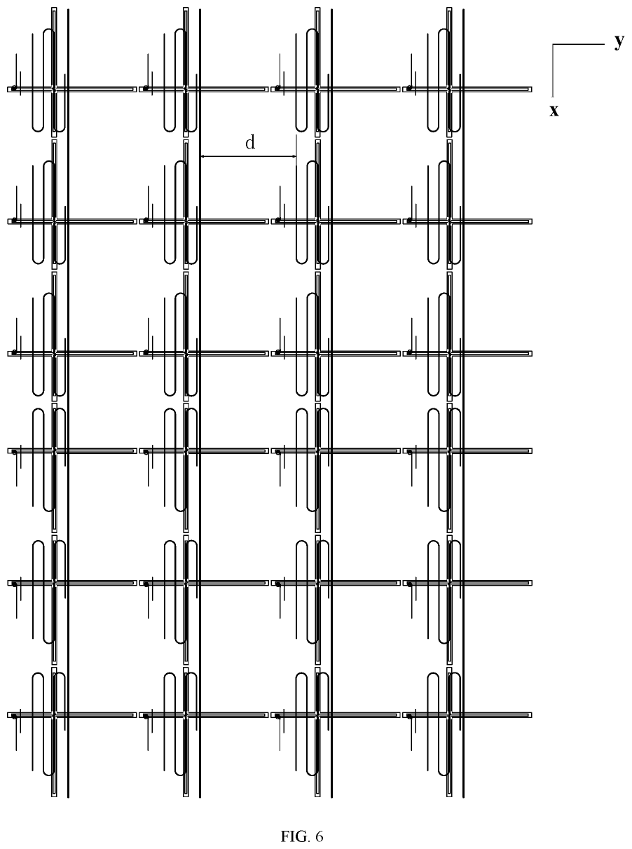

In this embodiment, the superconducting quantum circuit may include a plurality of quantum bits, each bit capacitor needs to be provided with one XY control line 32, and each Josephson junction 1 needs to be provided with one Z control line 31. Signal transmission between quantum bits can be realized by a fixed coupling between the quantum bits, i.e., a fixed gap is set between adjacent quantum bits, as shown in FIG. 6.

As an alternative embodiment, the number of the quantum bit is multiple; and two adjacent quantum bits are adjustably coupled.

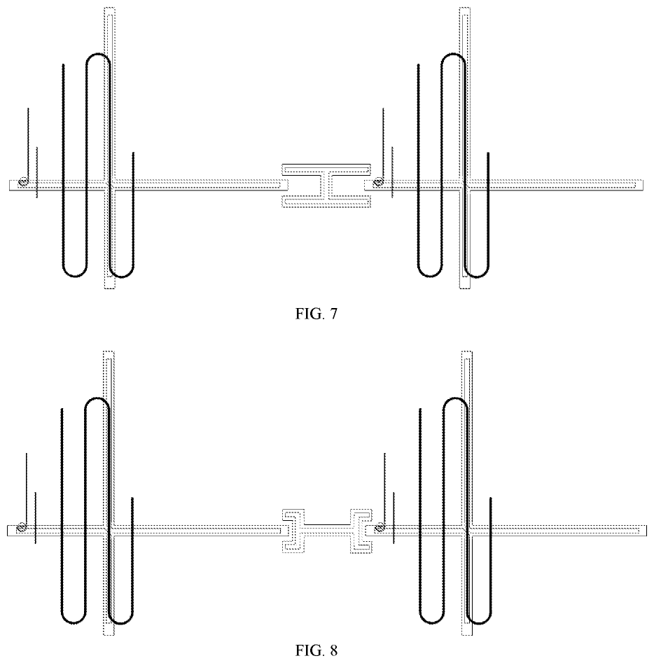

In this embodiment, the superconducting quantum circuit may include a plurality of quantum bits, each bit capacitor needs to be provided with one XY control line 32, and each Josephson junction 1 needs to be provided with one Z control line 31. Also, an adjustable coupling can be used between the quantum bits. If the adjustable coupling is selected, it is necessary to provide one Z control line 31 for each adjustably coupled quantum bit between two bits, as shown in FIG. 7. By using an adjustable coupling, an I-shaped adjustable coupling capacitor can be arranged between two adjacent quantum bits, and certainly, the I-shaped adjustable coupling capacitor can also be arranged as shown in FIG. 8. Both FIG. 7 and FIG. 8 take any two adjacent quantum bits as an example for illustration, and the arrangement solution of other two adjacent quantum bits is the same.

In an exemplary embodiment, referring to FIG. 6, a superconducting quantum circuit with a plurality of quantum bits in a fixed coupling is taken as an example, wherein each column of quantum bits (X-direction) leads six XY control lines 32 and six Z control lines 31 from the X-positive and X-negative directions, respectively, to the corners of the superconducting quantum chip (e.g., superconducting quantum chip), for bonding to the packaging box to complete the mounting and testing of the superconducting quantum chip. In order to reduce the crosstalk between the signal transmission lines, the distance between the signal transmission lines is selected as 50 μm. At this time, the distance between the read line 33 and the resonator 4 on the right side needs to satisfy: d≥50 μm×7=350 μm, so as to meet the layout requirement of the six signal lines.

Regarding the design value C_{q}=84 fF of the bit capacitor, based on the analysis of the novel bit capacitor structure proposed in this embodiment, C_{q1}=84 fF and C_{q2} takes any value, wherein 84 fF is taken herein. The upper and lower substrate materials are set to be sapphire with a thickness of 500 μm. Through simulation and analysis in Q3D software of Ansys suite, it can be obtained that the size of the bit capacitor corresponding to C_{q1} and C_{q2} is 345 μm×345 μm, and the size of the whole bit capacitor is 690 μm×690 μm. Regarding the quarter-wavelength resonator 4 with a resonance frequency design value of f=6.3 GHZ, the quarter-wavelength resonator 4 has a resonant length of about 5033 μm, and is arranged in the form of a meander line with a dimension of 550 μm*320 μm. The distance between the meander lines is 40 μm, and the two sides of the meander line are connected with an air bridge in a spanned mode to realize a good common ground. According to the size of the bit capacitor and the size of the resonator 4, it can be obtained that the distance d between the read line 33 and the resonator 4 on the right side is d=370 μm>350 μm, i.e., the novel bit capacitor structure provided in this embodiment ensures the isolation index of the signal line while avoiding the space waste of the signal line layout.

Regarding the same design values of C_{q}=84 fF and f=6.3 GHZ, the areas of the existing cross-shaped bit capacitor and resonator 4 in a meandering layout are 550 μm×550 μm and 420 μm×420 μm, respectively. The distance d between the read line 33 and the resonator 4 on the right side is d=130 μm<350 μm. At this time, the isolation index between the signal lines needs to be sacrificed to meet the wiring requirements.

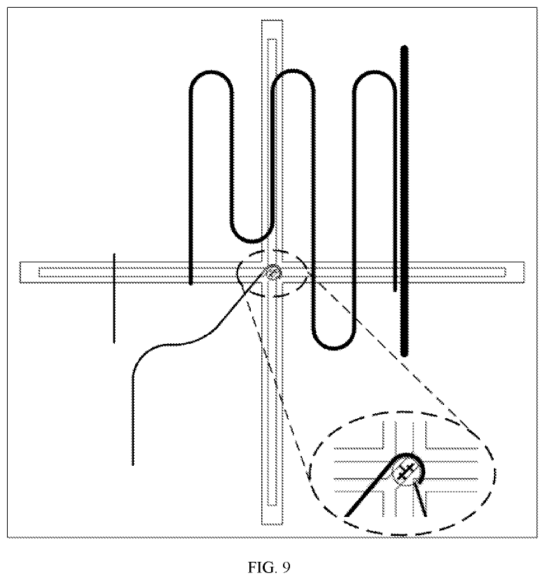

Similarly, regarding the same design values of C_{q}=84 fF and f=6.5 GHZ, according to the minimum size condition of the double-island bit capacitor, the bit capacitor has the minimum size: 1200 μm×1200 μm when C_{q1}=_{q2}=168 fF is taken. Considering that the Z control line 31 needs to extend to the central area of the bit capacitor, when wired, the resonator 4 needs to be routed around the lower left area in FIG. 9. At this time, the layout of resonator 4 corresponding to f=6.3 GHz is 480 μm×370 μm, and the distance between read line 33 and the resonator 4 on the right side is d=720 μm>350 μm. Obviously, although the double-island bit capacitor meets the requirements of signal line layout, the wiring needs to bypass the central area and the lower left corner area of the bit capacitor. In addition, the size of the bit capacitor is much larger than the size required by the signal line layout, resulting in wasted wiring space and reducing the integration level of the quantum chip.

In summary, the bit capacitor of the present disclosure has the following advantages over the cross-shaped bit capacitor and the double-island bit capacitor in the prior art: preventing the extension of the Z-control line to the central area of the bit capacitor, reducing the coupling strength between the Z-control line and the resonator, and facilitating the layout of the resonator and the signal line to the greatest extent; having a smaller minimum size of a bit capacitor, which is conducive to improving the integration level of the quantum chip, when the bit capacitor based on the double-island structure takes the minimum size, it needs to correspond to the condition C_{q1}=C_{q2}=2C_{q}, while when the novel bit capacitor provided by the present disclosure takes the minimum size, the required condition is that C_{q1}~C_{q}, and C_{q2} takes any value, the novel bit capacitor provided by the present disclosure has smaller minimum size of the bit capacitor, which is conducive to improving the integration level of the quantum chip; being flexible in design, thanks to the fact that C_{q2} can be adjusted to any value according to the layout requirements. When the number of the control lines is changed (for example, the number of the resonators mounted on a single read line is changed or the coupling between the bit capacitors is modified from fixed coupling to adjustable coupling), there is no need to redesign the bit capacitor, and the adjustment of the size of the C_{q2} self-capacitor can meet the requirements of the signal line layout, which is conducive to improving the speed of the version iteration.

In a second aspect, the present disclosure further provides a superconducting quantum chip comprising the superconducting quantum circuit according to any one of the above embodiments.

The description of the superconducting quantum chip provided by the present disclosure can be referred to the above embodiments, which will not be described in detail herein.

The superconducting quantum chip provided by the present disclosure has the same advantageous effects as the superconducting quantum circuit.

It should also be noted that relationship terms such as first and second, etc. are used herein only to distinguish one entity or operation from another without necessarily requiring or implying any such actual relationship or order between those entities or operations. Moreover, the terms “comprise”, “include” or any other variation thereof, are intended to cover a non-exclusive inclusion, such that a process, a method, an article, or an apparatus comprising a list of elements includes not only those elements, but also other elements not explicitly listed or may include elements inherent to the process, method, article, or apparatus. Without further limitation, an element defined by the statement of “comprising a . . . ” does not exclude the further presence of additionally identical elements in a process, a method, an article or an apparatus comprising said element.

The above description of the disclosed embodiments enables those skilled in the art to implement or use the present disclosure. Various modifications to these embodiments will be apparent to those skilled in the art, and the general principles defined herein may be implemented in other embodiments without departing from the spirit or scope of the present disclosure. Accordingly, the present disclosure will not be limited to those embodiments shown herein, but will conform to the broadest scope consistent with the principles and novel features disclosed herein.

What is claimed is:

1. A superconducting quantum circuit, comprising:
a quantum bit including a bit capacitor and a Josephson junction, the bit capacitor including two independent metal sheets, the Josephson junction being connected between one of the metal sheets and a ground plane in a spanned mode, a first coupling capacitor being formed between the two metal sheets, and a self-capacitor being formed between each of the metal sheets and the ground plane; and
a signal transmission line, the signal transmission line being coupled with the quantum bit.

2. The superconducting quantum circuit according to claim 1, wherein the bit capacitor comprises a first metal sheet and a second metal sheet, a size of the first metal sheet being smaller than a size of the second metal sheet, and the Josephson junction is connected between the first metal sheet and the ground plane in a spanned mode.

3. The superconducting quantum circuit according to claim 1, further comprising: a first substrate having the quantum bit formed on an upper surface of the first substrate; and a second substrate having the signal transmission line formed on a lower surface of the second substrate.

4. The superconducting quantum circuit according to claim 3, wherein the upper surface of the first substrate and the lower surface of the second substrate are both made of superconducting materials.

5. The superconducting quantum circuit according to claim 1, further comprising: a resonator coupled to the quantum bit and forming a second coupling capacitor between the resonator and each of the metal sheets.

6. The superconducting quantum circuit according to claim 1, wherein the signal transmission line is in non-coplanar coupling with the quantum bit.

7. The superconducting quantum circuit according to claim 1, wherein the signal transmission line comprises a Z control line which is coupled with the Josephson junction through mutual inductance;
and/or
the signal transmission line comprises an XY control line which is coupled with the bit capacitor through mutual capacitance.

8. The superconducting quantum circuit according to claim 1, wherein the number of the quantum bit is multiple; and the two adjacent quantum bits are fixedly coupled.

9. The superconducting quantum circuit according to claim 1, wherein the number of the quantum bits is multiple; and the two adjacent quantum bits are adjustably coupled.

10. A superconducting quantum chip comprising the superconducting quantum circuit according to claim 1.
